(19) United States
(12) Patent Application Publication
(10) Pub. No.: US 2026/0198194 A1
(43) Pub. Date: Jul. 9, 2026

(54) DISPLAY PANEL AND DISPLAY APPARATUS

(71) Applicants: Hefei Visionox Technology Co., Ltd., Hefei (CN); Visionox Technology Inc., Kunshan (CN)

(72) Inventors: Zhiwei ZHOU, Hefei (CN); Qingfeng XU, Hefei (CN); Jinfang ZHANG, Hefei (CN); Yingyu FENG, Kunshan (CN)

(73) Assignees: Hefei Visionox Technology Co., Ltd., Hefei (CN); Visionox Technology Inc., Kunshan (CN)

(21) Appl. No.: 19/396,217

(22) Filed: Nov. 20, 2025

(30) Foreign Application Priority Data
Nov. 29, 2024 (CN) 202411754052.8

(51) Int. Cl. H10K 59/131; H10K 59/121; H10K 59/122

(52) U.S. Cl. CPC H10K 59/131; H10K 59/121; H10K 59/122

(57) ABSTRACT

The present application provides a display panel and a display apparatus. The display panel includes a substrate, a drive circuit layer, a pixel definition layer, and a plurality of light-emitting devices. In the display panel provided in the present application, an orthographic projection of a first via on a substrate is at a first shortest distance from an orthographic projection of a corresponding one of first pixel openings on the substrate, and an orthographic projection of a second via on the substrate is at a second shortest distance from an orthographic projection of a corresponding one of second pixel openings on the substrate, the first shortest distance being not equal to the second shortest distance, which is conducive to compressing the space outside the pixel openings, thereby increasing a pixel aperture ratio, enhancing the brightness of the display panel, and improving the display performance of the display panel.

### CROSS-REFERENCE TO RELATED APPLICATIONS

The present application claims priority to the Chinese Patent Application No. CN 202411754052.8, filed on Nov. 29, 2024, and the entire contents of the aforementioned application are hereby incorporated by reference in its entirety.

### FIELD

The present application relates to the field of display, and specifically to a display panel and a display apparatus.

### BACKGROUND

Organic light-emitting diodes (OLEDs) and flat panel display apparatuses based on technologies such as light-emitting diodes (LEDs) have been widely used in various consumer electronics such as mobile phones, televisions, notebook computers, and desktop computers, and predominate in display apparatuses thanks to their advantages such as high image quality, energy efficiency, slim design, and a wide range of applications.

During the preparation of conventional OLED display panels, light-emitting pixel patterning is usually implemented by means of a fine metal mask (FMM). FMM technology is mature and has rich experience in mass production. However, FMM technology also has problems such as limited accuracy, and high costs. Fine metal mask-free technology eliminates the limitations of conventional OLED processes on display size, resolution, and other screen performances, and has the advantages of high performance, full-size coverage, and agile delivery. Reference can be made to relevant contents of the fine metal mask-free technology recited in Chinese patents CN118251982A, CN115666161A, CN116648095A, CN117062489A, CN118678742A, CN118785761A, CN115224220A, CN118678729A, CN118660529A and CN118660589A.

However, the usage performance of conventional OLED display products needs to be improved.

### SUMMARY

One or more embodiments of the present application provides a display panel. The display panel includes: a substrate; a drive circuit layer disposed on a side of the substrate and provided with a plurality of pixel drive units and a plurality of vias, the plurality of pixel drive units including a plurality of first pixel drive units and a plurality of second pixel drive units, and the plurality of vias including a plurality of first vias and a plurality of second vias;

a pixel definition layer disposed on a side of the drive circuit layer away from the substrate and defining a plurality of pixel openings, the plurality of pixel openings including a plurality of first pixel openings and a plurality of second pixel openings; and a plurality of light-emitting devices including a plurality of first light-emitting devices and a plurality of second light-emitting devices, the first light-emitting device being partially disposed in a corresponding one of the plurality of first pixel openings and electrically connected to a corresponding one of the plurality of first pixel drive units through a corresponding one of the plurality of first vias, and the second light-emitting device being disposed in a corresponding one of the plurality of second pixel openings and electrically connected to a corresponding one of the plurality of second pixel drive units through a corresponding one of the plurality of second vias;

wherein, an orthographic projection of the first via on the substrate is at a first shortest distance from an orthographic projection of the corresponding first pixel opening on the substrate, and an orthographic projection of the second via on the substrate is at a second shortest distance from an orthographic projection of the corresponding second pixel opening on the substrate, the first shortest distance being not equal to the second shortest distance.

One or more embodiments of the present application provides a display panel. The display panel includes:
a substrate;
a drive circuit layer disposed on a side of the substrate and provided with a plurality of pixel drive units and a plurality of vias, the plurality of pixel drive units including a plurality of first pixel drive units, a plurality of second pixel drive units, and a plurality of third pixel drive units, and the plurality of vias including a plurality of first vias, a plurality of second vias, and a plurality of third vias;
a pixel definition layer disposed on the side of the drive circuit layer away from the substrate and defining a plurality of pixel openings, the plurality of pixel openings including a plurality of first pixel openings, a plurality of second pixel openings, and a plurality of third pixel openings;
isolation structures disposed on a side of the pixel definition layer away from the substrate and enclosing a plurality of isolation openings in communication with corresponding pixel openings; and
a plurality of light-emitting devices including a plurality of first light-emitting devices, a plurality of second light-emitting devices, and a plurality of third light-emitting devices, the first light-emitting device being partially disposed in a corresponding one of the plurality of first pixel openings and electrically connected to a corresponding one of the plurality of first pixel drive units through a corresponding one of the plurality of first vias, the second light-emitting device being disposed in a corresponding one of the plurality of second pixel openings and electrically connected to a corresponding one of the plurality of second pixel drive units through a corresponding one of the plurality of second vias, and the third light-emitting device being disposed in a corresponding one of the plurality of third pixel openings and electrically connected to a corresponding one of the plurality of third pixel drive units through a corresponding one of the plurality of third vias;
wherein an orthographic projection of the first via on the substrate is at a first shortest distance from an orthographic projection of the corresponding first pixel opening on the substrate, an orthographic projection of the second via on the substrate is at a second shortest distance from an orthographic projection of the corresponding second pixel opening on the substrate, and an orthographic projection of the third via on the substrate is at a third shortest distance from an orthographic projection of the corresponding third pixel opening on the substrate, at least two of the first shortest distance, the second shortest distance and the third shortest distance being not equal.

One or more embodiments of the present application discloses a display apparatus including a display panel described above.

Compared with the prior art, in the display panel provided in the present application, the orthographic projection of the first via on the substrate is at the first shortest distance from the orthographic projection of the corresponding first pixel opening on the substrate, and the orthographic projection of the second via on the substrate is at the second shortest distance from the orthographic projection of the corresponding second pixel opening on the substrate, the first shortest distance being not equal to the second shortest distance, which is conducive to compressing the space outside the pixel openings, thereby increasing a pixel aperture ratio, enhancing the brightness of the display panel, and improving the display performance of the display panel.

### BRIEF DESCRIPTION OF THE DRAWINGS

FIG. 1 is a schematic diagram of a display panel in the prior art;

FIG. 2 is a schematic diagram of a layer structure of a display panel in the prior art;

FIG. 3 is a schematic diagram of a layer structure of a display panel according to one or more embodiments of the present application;

FIG. 4 is a partial structural schematic diagram of a display panel according to one or more embodiments of the present application;

FIG. 5 is a partial structural schematic diagram of a display panel according to one or more embodiments of the present application;

FIG. 6 is a partial structural schematic diagram of a display panel according to one or more embodiments of the present application;

FIG. 7 is a schematic diagram of a layer structure of a display panel according to one or more embodiments of the present application;

FIG. 8 is a schematic diagram of a layer structure of a display panel according to one or more embodiments of the present application;

FIG. 9 is a schematic diagram of an isolation structure according to one or more embodiments of the present application.

### LIST OF REFERENCE SIGNS

100. Display panel;
1. Substrate; a. First shortest distance; b. Second shortest distance; c. Third shortest distance; d. Fourth shortest distance; e. Fifth shortest distance;
C1. First straight portion; C2. Second straight portion; C3. Third straight portion; C4. Fourth straight portion; C5. Fifth straight portion; C6. Sixth straight portion; C7. Seventh straight portion; C8. Eighth straight portion; C9. Ninth straight portion; C10. Tenth straight portion; C11. Eleventh straight portion; C12. Twelfth straight portion;
D1. First curved portion; D2. Second curved portion; D3. Third curved portion; D4. Fourth curved portion; D5. Fifth curved portion; D6. Sixth curved portion; D7. Seventh curved portion; D8. Eighth curved portion; D9. Ninth curved portion; D10. Tenth curved portion;
2. Isolation structure; 21. Isolation opening; 23. First support portion; 231. First sub-support portion; 232. Second sub-support portion; 24. Second support portion;
3. Light-emitting device; 31. Lower electrode; 311. First lower electrode; 312. Second lower electrode; 313. Third lower electrode; 32. Light-emitting layer; 33. Upper electrode;
4. Drive circuit layer;
51. Via; 511. First via; 512. Second via; 513. Third via;
6. Pixel definition layer; 61. Pixel opening; 611. First pixel opening; 612. Second pixel opening; 613. Third pixel opening; 62. Concave portion.

### DETAILED DESCRIPTION OF THE EMBODIMENTS

Terms such as “first” and “second” in the description, claims, and above drawings of the present application are used to distinguish between similar objects and are not necessarily used to describe a particular order or sequence. It is to be understood that data used in this manner is interchangeable in appropriate cases and the embodiments of the present application described herein can also be implemented in an order not illustrated or described herein. In addition, terms “comprising”, “including”, and any variation thereof are intended to encompass a non-exclusive inclusion. For example, a process, method, system, product, or device that includes a series of steps or units not only includes the expressly listed steps or units, but may also include other steps or units that are not expressly listed or are inherent to such a process, method, product, or device.

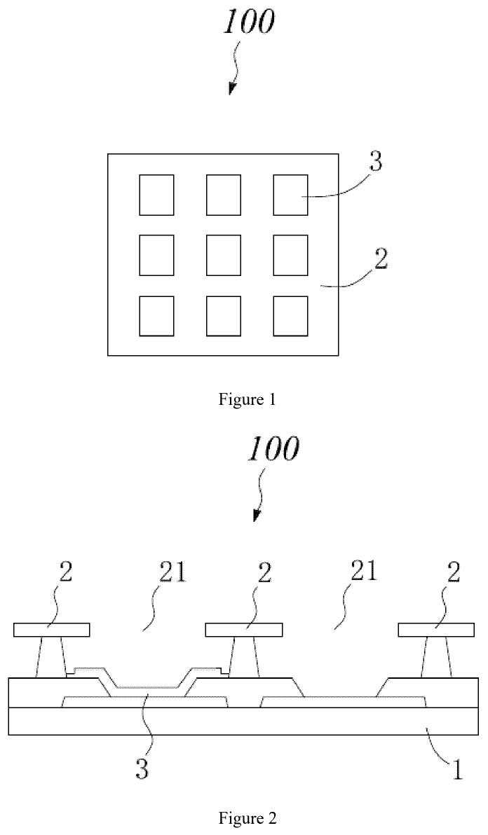

FIGS. 1 and 2 are schematic diagrams of a structure of a display panel in the prior art. The display panel 100 includes a substrate 1 and isolation structures 2 disposed on a side of the substrate 1. The isolation structures 2 enclose isolation openings 21 for accommodating light-emitting devices 3, and adjacent light-emitting devices 3 are separated by the isolation structures 2.

The isolation structures 2 are provided at gaps between the light-emitting devices 3 to separate functional film layers of the adjacent light-emitting devices 3, and in an evaporation process for the plurality of functional film layers, it is only necessary to perform full-surface evaporation on the display panel 100, without using a mask to perform evaporation in regions in which the light emitting devices 3 are located to form the function film layers. In this way, the evaporation process using the isolation structures 2 does not need to consider the alignment accuracy during evaporation, and the gaps between the light-emitting devices 3 can be designed to be smaller in size to increase the pixel density.

However, in the display panel 100 of the above structure, as the pixels per inch (PPI) increases, pixel openings become smaller accordingly, and the pixel aperture ratio cannot be increased, resulting in relatively low brightness of the display panel.

In view of this, the present application provides a solution of a display panel, as detailed in the following embodiments.

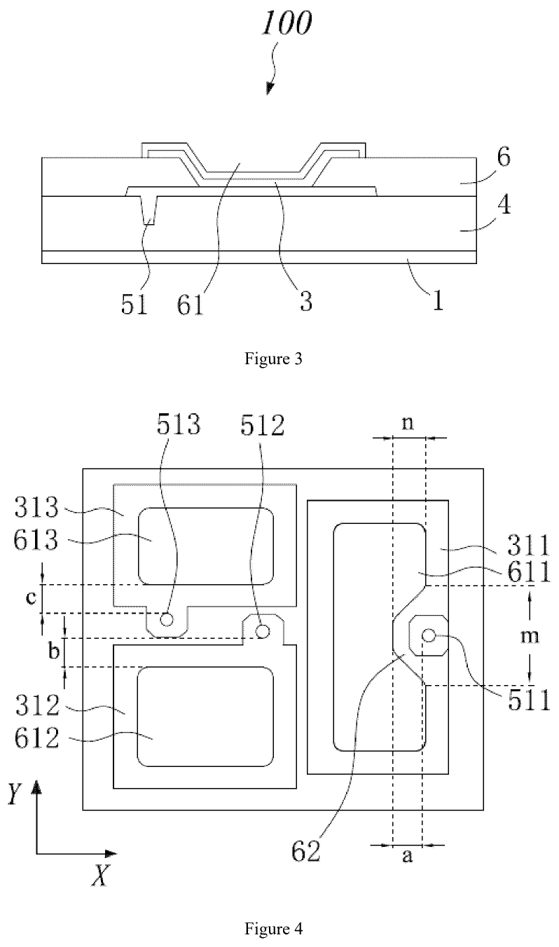

Referring to FIGS. 3 and 4, an embodiment of the present application provides a display panel 100 which includes a substrate 1, a drive circuit layer 4, a pixel definition layer 6, and a plurality of light-emitting devices 3.

The drive circuit layer 4 is disposed on a side of the substrate 1. The drive circuit layer 4 is provided with a plurality of pixel drive units and a plurality of vias 51. The plurality of pixel drive units include a plurality of first pixel drive units and a plurality of second pixel drive units, and the plurality of vias 51 include a plurality of first vias 511 and a plurality of second vias 512.

The pixel definition layer 6 is disposed on a side of the drive circuit layer 4 away from the substrate 1. The pixel definition layer 6 defines a plurality of pixel openings 61. The plurality of pixel openings 61 include a plurality of first pixel openings 611 and a plurality of second pixel openings 612.

The plurality of light-emitting devices 3 include a plurality of first light-emitting devices and a plurality of second light-emitting devices. The first light-emitting device is partially disposed in a corresponding one of the plurality of first pixel openings 611 and is electrically connected to a corresponding one of the plurality of first pixel drive units through a corresponding one of the plurality of first vias 511, and the second light-emitting device is partially disposed in a corresponding one of the plurality of second pixel openings 612 and is electrically connected to a corresponding one of the plurality of second pixel drive units through a corresponding one of the plurality of second vias 512.

An orthographic projection of the first via 511 on the substrate 1 is at a first shortest distance a from an orthographic projection of the corresponding first pixel opening 611 on the substrate 1, and an orthographic projection of the second via 512 on the substrate 1 is at a second shortest distance b from an orthographic projection of the corresponding second pixel opening 612 on the substrate 1. The first shortest distance a is not equal to the second shortest distance b.

In the display panel 100 provided in the present application, the orthographic projection of the first via 511(or each first via 511) on the substrate 1 is at the first shortest distance a from the orthographic projection of the corresponding first pixel opening 611 on the substrate 1, and the orthographic projection of the second via 512 (or each second via 512) on the substrate 1 is at the second shortest distance b from the orthographic projection of the corresponding second pixel opening 612 on the substrate 1, the first shortest distance a being not equal to the second shortest distance b, which is conducive to compressing the space outside the pixel openings, thereby increasing a pixel aperture ratio, enhancing the brightness of the display panel, and improving the display performance of the display panel.

Still referring to FIG. 4, in one of the embodiments, the first shortest distance a is not greater than the second shortest distance b, which is conducive to compressing the space outside the first pixel openings 611, thereby increasing the pixel aperture ratio.

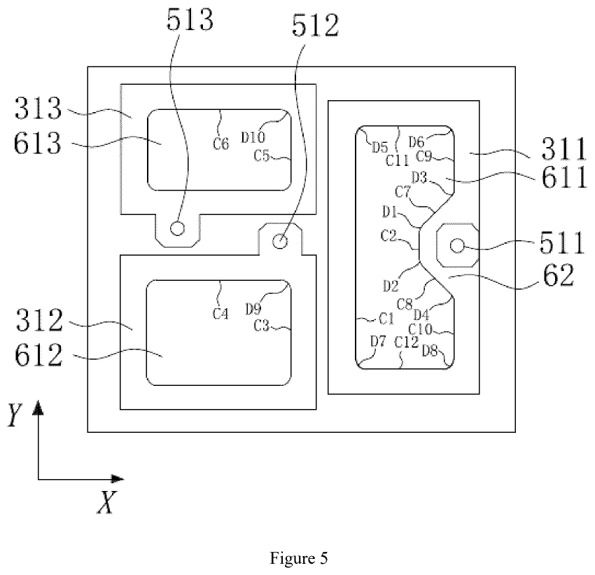

Referring to FIG. 5, in one of the embodiments, an edge of the first pixel opening 611(or each first pixel opening 611) includes a first straight portion C1 extending in a first direction (e.g., a Y direction in the figure) and a concave portion 62 that is concave toward the first straight portion C1. The concave portion 62 includes a second straight portion C2 close to the first straight portion C1 in a second direction (e.g., an X direction in the figure), and the orthographic projection of the first via 511 on the substrate 1 is located on a side of an orthographic projection of the corresponding second straight portion C2 on the substrate 1 away from an orthographic projection of the corresponding first straight portion C1 on the substrate 1, the first direction intersecting with the second direction. A shortest distance between the orthographic projection of the first via 511 on the substrate 1 and the orthographic projection of the corresponding second straight portion C2 on the substrate 1 is the first shortest distance a. The concave portion 62 is configured to provide clearance for the corresponding first via 511, which is conducive to compressing the space outside the first pixel openings 611, thereby increasing the pixel aperture ratio.

The second direction may be at 70 degrees, 80 degrees, 85 degrees, etc. relative to the first direction. In some implementations, the second direction is at 90 degrees relative to the first direction, that is, the second direction is perpendicular to the first direction.

In some implementations, an edge of the second pixel opening 612(or each second pixel opening 612) includes a plurality of third straight portions C3 extending in the first direction and a plurality of fourth straight portions C4 extending in the second direction, and a shortest distance between the orthographic projection of the second via on the substrate 1 and an orthographic projection of the corresponding fourth straight portion C4 on the substrate 1 is the second shortest distance b.

In some implementations, a length of the second straight portion C2 is less than a length of the first straight portion C1.

In some implementations, the first straight portion C1 is parallel to the second straight portion C2.

In one of the embodiments, an emitting color of the first light-emitting device is different from an emitting color of the second light-emitting device, thereby improving the richness of display.

In some implementations, the plurality of pixel drive units further include a plurality of third pixel drive units, the plurality of vias 51 further include a plurality of third vias 513, the plurality of pixel openings 61 further include a plurality of third pixel openings 613, and the plurality of light-emitting devices 3 further include a plurality of third light-emitting devices. The third light-emitting device is partially disposed in a corresponding one of the plurality of third pixel openings 613 and is electrically connected to a corresponding one of the plurality of third pixel drive units through a corresponding one of the plurality of third vias 513. An orthographic projection of the third via 513 on the substrate 1 is at a third shortest distance c from an orthographic projection of the corresponding third pixel opening 613 on the substrate 1, and the first shortest distance a is not equal to the third shortest distance c. This is conducive to compressing the space outside the first pixel openings 611 and the third pixel openings 613, thereby increasing the pixel aperture ratio.

In some implementations, the first shortest distance a is not greater than the third shortest distance c.

In some implementations, an edge of the third pixel opening 613(or each third pixel opening 613) includes a plurality of fifth straight portions C5 extending in the first direction and a plurality of sixth straight portions C6 extending in the second direction, and a shortest distance between the orthographic projection of the third via 513 on the substrate 1 and an orthographic projection of the corresponding sixth straight portion C6 on the substrate 1 is the third shortest distance c.

In some implementations, the emitting color of the first light-emitting device, the emitting color of the second light-emitting device, and an emitting color of the third light-emitting device are different from each other, thereby improving the richness of display.

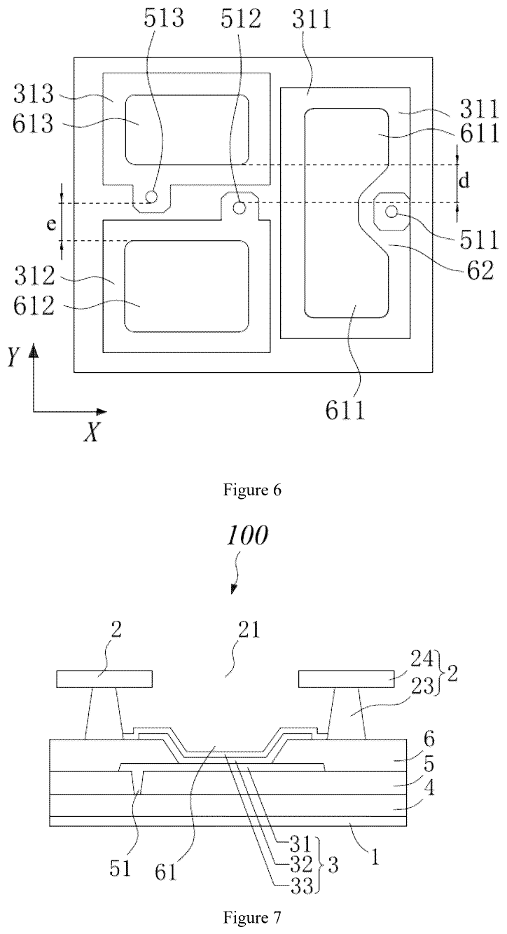

Referring to FIG. 6, in one of the embodiments, the orthographic projection of the second via 512 (or each second via 512) on the substrate 1 is at a fourth shortest distance d from an orthographic projection of the third pixel opening 613 adjacent to the second via 512 on the substrate 1, and the fourth shortest distance d is not equal to the second shortest distance b, which is conducive to compressing the space outside the pixel openings, thereby increasing the pixel aperture ratio.

In some implementations, the fourth shortest distance d is greater than the second shortest distance b.

In some implementations, the shortest distance between the orthographic projection of the second via 512 on the substrate 1 and an orthographic projection of the corresponding sixth straight portion C6 on the substrate 1 is the fourth shortest distance d.

In some implementations, the orthographic projection of the third via 513 on the substrate 1 is at a fifth shortest distance e from an orthographic projection of the second pixel opening 612 adjacent the third via 513 on the substrate 1, and the fifth shortest distance e is not equal to the third shortest distance c. The distances between each via and other pixel openings are set to be less than the distance between this via and the corresponding pixel opening, thereby increasing the pixel aperture ratio.

In some implementations, the fifth shortest distance e is greater than the third shortest distance c.

In some implementations, the shortest distance between the orthographic projection of the third via 513 on the substrate 1 and an orthographic projection of the corresponding fourth straight portion C4 on the substrate 1 is the fifth shortest distance e.

In some implementations, the orthographic projections of the second via 512 and third via 513 on the substrate 1 are located between the orthographic projection of the corresponding second pixel opening 612 on the substrate 1 and the orthographic projection of the corresponding third pixel opening 613 on the substrate 1, thereby increasing the pixel aperture ratio.

Still referring to FIG. 6, in one of the embodiments, the concave portion 62 has a first dimension in the first direction, and the concave portion 62 has a second dimension in the second direction, the first dimension being greater than the second dimension, which is conducive to further compressing of the space outside the first pixel openings 611, thereby increasing the pixel aperture ratio.

The influence of the dimension of the concave portion 62 in the second direction on the pixel aperture ratio is greater than that of the dimension of the concave portion 62 in the first direction on the pixel aperture ratio. Therefore, in this embodiment, the maximum dimension of the concave portion 62 in the second direction is set to be relatively small to ensure that the dimension of the pixel opening 61 in the second direction is large enough, while the maximum dimension of the concave portion 62 in the first direction is set to be relatively large to meet the requirement of an extreme distance between the pixel opening 61 and the via 51, thereby avoiding interference between the via 51 and the pixel opening 61.

In some implementations, the first dimension and the second dimension satisfy M>1.5 n, where m is the first dimension, and n is the second dimension. For example, m=1.6 n, m=1.7 n, m=1.8 n, m=2 n, etc. The pixel aperture ratio can be further increased based on this dimension relationship. In some implementations, m>2 n, for example, M=2.1 n, m=2.5 n, m=3 n, m=4 n, etc.

Still referring to FIG. 5, in one of the embodiments, the concave portion 62 further includes:
a seventh straight portion C7 and a first curved portion D1, where the first curved portion D1 is connected to a first end of the second straight portion C2 and a first end of the seventh straight portion C7, and an included angle between the second straight portion C2 and the seventh straight portion C7 is not less than 90 degrees; or
an eighth straight portion C8 and a second curved portion D2, where the second curved portion D2 is connected to a second end of the second straight portion C2 and a first end of the eighth straight portion C8, and an included angle between the second straight portion C2 and the eighth straight portion C8 is not less than 90 degrees.

As an example, an included angle between the second straight portion C2 and the seventh straight portion C7 is not less than 90 degrees, and an included angle between the second straight portion C2 and the eighth straight portion C8 is not less than 90 degrees.

As an example, the included angle between the second straight portion C2 and the seventh straight portion C7 is 90 degrees, 95 degrees, 100 degrees, 120 degrees, etc., which is not specifically limited.

As an example, the included angle between the second straight portion C2 and the eighth straight portion C8 is 90 degrees, 95 degrees, 100 degrees, 120 degrees, etc., which is not specifically limited.

In some implementations, the seventh straight portion C7 and the eighth straight portion C8 are located on a side of the second straight portion C2 away from the first straight portion C1.

In some implementations, the edge of the first pixel opening 611 further includes:
a ninth straight portion C9 and a tenth straight portion C10, where the ninth straight portion C9 and the tenth straight portion C10 are located on the side of the second straight portion C2 away from the first straight portion C1, and a portion of the orthographic projection of the first via on the substrate 1 is located between an orthographic projection of the ninth straight portion C9 on the substrate 1 and an orthographic projection of the tenth straight portion C10 on the substrate 1; and
a third curved portion D3 and a fourth curved portion D4, where the third curved portion D3 is connected to a second end of the seventh straight portion C7 and a first end of the ninth straight portion C9, with an included angle between the seventh straight portion C7 and the ninth straight portion C9 being not less than 90 degrees, and the fourth curved portion D4 is connected to a second end of the eighth straight portion C8 and a first end of the tenth straight portion C10, with an included angle between the eighth straight portion C8 and the tenth straight portion C10 being not less than 90 degrees.

As an example, the included angle between the eighth straight portion C8 and the tenth straight portion C10 is 90 degrees, 95 degrees, 100 degrees, 120 degrees, etc., which is not specifically limited.

In some implementations, the ninth straight portion C9 is parallel to the first straight portion C1, or the tenth straight portion C10 is parallel to the first straight portion C1.

As an example, the ninth straight portion C9 is parallel to the first straight portion C1, and the tenth straight portion C10 is parallel to the first straight portion C1.

In some implementations, the edge of the first pixel opening 611 further includes:
an eleventh straight portion C11, a fifth curved portion D5, and a sixth curved portion D6, where the fifth curved portion D5 is connected to a first end of the first straight portion C1 and a first end of the eleventh straight portion C11, the sixth curved portion D6 is connected to a second end of the eleventh straight portion C11 and a second end of the ninth straight portion C9, and the eleventh straight portion C11 extends in the second direction; and
a twelfth straight portion C12, a seventh curved portion D7, and an eighth curved portion D8, where the seventh curved portion D7 is connected to a second end of the first straight portion C1 and a first end of the twelfth straight portion C12, the eighth curved portion D8 is connected to a second end of the twelfth straight portion C12 and a second end of the tenth straight portion C10, and the twelfth straight portion C12 extends in the second direction.

In some implementations, a length of the first straight portion C1 is greater than a length of the eleventh straight portion C11, or the length of the first straight portion C1 is greater than a length of the twelfth straight portion C12.

As an example, a length of the first straight portion C1 is greater than a length of the eleventh straight portion C11, and the length of the first straight portion C1 is greater than a length of the twelfth straight portion C12.

In some implementations, an included angle between the eleventh straight portion C11 and the first straight portion C1 is not less than 90 degrees, or an included angle between the eleventh straight portion C11 and the ninth straight portion C9 is not less than 90 degrees, or an included angle between the twelfth straight portion C12 and the first straight portion C1 is not less than 90 degrees, or an included angle between the twelfth straight portion C12 and the tenth straight portion C10 is not less than 90 degrees.

As an example, an included angle between the eleventh straight portion C11 and the first straight portion C1 is not less than 90 degrees, and an included angle between the eleventh straight portion C11 and the ninth straight portion C9 is not less than 90 degrees.

As an example, an included angle between the twelfth straight portion C12 and the first straight portion C1 is not less than 90 degrees, and an included angle between the twelfth straight portion C12 and the tenth straight portion C10 is not less than 90 degrees.

As an example, an included angle between the eleventh straight portion C11 and the first straight portion C1 is not less than 90 degrees, and an included angle between the twelfth straight portion C12 and the first straight portion C1 is not less than 90 degrees.

As an example, the included angle between the eleventh straight portion C11 and the first straight portion C1 is 90 degrees, 95 degrees, 100 degrees, 120 degrees, etc., which is not specifically limited.

As an example, the included angle between the eleventh straight portion C11 and the ninth straight portion C9 is 90 degrees, 95 degrees, 100 degrees, 120 degrees, etc., which is not specifically limited.

As an example, the included angle between the twelfth straight portion C12 and the first straight portion C1 is 90 degrees, 95 degrees, 100 degrees, 120 degrees, etc., which is not specifically limited.

As an example, the included angle between the twelfth straight portion C12 and the tenth straight portion C10 is 90 degrees, 95 degrees, 100 degrees, 120 degrees, etc., which is not specifically limited.

In some implementations, the edge of the second pixel opening 612 further includes
a plurality of ninth curved portions D9, and the ninth curved portion D9 is connected between the corresponding adjacent third straight portion C3 and fourth straight portion C4, and an included angle between the third straight portion C3 and the fourth straight portion C4 is not less than 90 degrees.

As an example, the included angle between the third straight portion C3 and the fourth straight portion C4 is 90 degrees, 95 degrees, 100 degrees, 120 degrees, etc., which is not specifically limited.

In some implementations, the edge of the third pixel opening 613 further includes
a plurality of tenth curved portions D10, and the tenth curved portion D10 is connected between the corresponding adjacent fifth straight portion C5 and sixth straight portion C6, and an included angle between the fifth straight portion C5 and the sixth straight portion C6 is not less than 90 degrees.

As an example, the included angle between the fifth straight portion C5 and the sixth straight portion C6 is 90 degrees, 95 degrees, 100 degrees, 120 degrees, etc., which is not specifically limited.

The light-emitting device 3 includes an upper electrode 33 and a lower electrode 31. In some implementations, the lower electrode 31 is an anode, and the upper electrode 33 is a cathode.

In one of the embodiments, the first light-emitting device includes a first lower electrode 311, the second light-emitting device includes a second lower electrode 312, and the third light-emitting device includes a third lower electrode 313, where a part of a structure of the first lower electrode 311 extends to the corresponding first via 511 and is electrically connected to the corresponding first pixel drive unit, a part of a structure of the second lower electrode 312 extends to the corresponding second via 512 and is electrically connected to the corresponding second pixel drive unit, and a part of a structure of the third lower electrode 313 extends to the corresponding third via 513 and is electrically connected to the corresponding third pixel drive unit.

In some implementations, a portion of the first lower electrode 311 is disposed between the drive circuit layer 4 and the pixel definition layer 6, and the other portion is exposed from the corresponding first pixel opening 611; a portion of the second lower electrode 312 disposed between the drive circuit layer 4 and the pixel definition layer 6, and the other portion is exposed from the corresponding second pixel opening 612; and a portion of the third lower electrode 313 is disposed between the drive circuit layer 4 and the pixel definition layer 6, and the other portion is exposed from the corresponding third pixel opening 613.

In one of the embodiments, the emitting color of the first light-emitting device is blue, the emitting color of the second light-emitting device is either red or green, and the emitting color of the third light-emitting device is the other one of red and green.

In some implementations, an area of the first pixel opening 611 is greater than an area of the second pixel opening 612, or the area of the first pixel opening 611 is greater than an area of the third pixel opening 613.

As an example, an area of the first pixel opening 611 is greater than an area of the second pixel opening 612, and the area of the first pixel opening 611 is greater than an area of the third pixel opening 613.

Still referring to FIG. 5, in one of the embodiments, the display panel 100 includes a plurality of pixels which are arranged in an array and include first light-emitting devices, second light-emitting devices and third light-emitting devices. In one pixel, the orthographic projection of the second via 512 corresponding to the second light-emitting device on the substrate 1 and the orthographic projection of the third via 513 corresponding to the third light-emitting device on the substrate are located between the orthographic projection of the second pixel opening 612 corresponding to the second light-emitting device on the substrate 1 and the orthographic projection of the third pixel opening 613 corresponding to the third light-emitting device on the substrate 1, thereby increasing the pixel aperture ratio.

In some implementations, in the same pixel, the first light-emitting device and the second light-emitting device are arranged in the second direction, the first light-emitting device and the third light-emitting device are arranged in the second direction, the second light-emitting device and the third light-emitting device are arranged in the first direction, and the second light-emitting device and the third light-emitting device are on the same side of the first light-emitting device.

In one of the embodiments, the display panel 100 includes a plurality of first pixel columns and a plurality of second pixel columns which are arranged alternately in the second direction, where the first pixel column (or each first pixel column) includes a plurality of first light-emitting devices arranged in the first direction, and the second pixel column (or each second pixel column) includes a plurality of second light-emitting devices and a plurality of third light-emitting devices which are arranged alternately in the first direction.

Referring to FIG. 7, in one of the embodiments, the display panel 100 further includes an isolation structure 2. The isolation structure 2 is disposed on a side of the drive circuit layer 4 away from the substrate 1, the isolation structure 2 enclose a plurality of isolation openings 21, and the isolation openings 21 are in communication with corresponding pixel openings 61. The isolation structure 2 are provided between the light-emitting devices 3 to separate functional film layers of the adjacent light-emitting devices 3, and in an evaporation process for the plurality of functional film layers, it is only necessary to perform full-surface evaporation on the display panel 100, without using a mask to perform evaporation in regions in which the light emitting devices 3 are located to form the function film layers. In this way, the evaporation process using the isolation structure 2 does not need to consider the alignment accuracy during evaporation, and the gaps between the light-emitting devices 3 can be designed to be smaller in size to increase the pixel density.

In some implementations, the isolation structure 2 are located on a side of the pixel definition layer 6 away from the substrate 1.

Still referring to FIG. 7, in one of the embodiments, the isolation structure 2 includes a first support portion 23 and a second support portion 24, where the second support portion 24 is located on a side of the first support portion 23 away from the substrate 1, and an orthographic projection of an end of the first support portion 23 close to the second support portion 24 on the substrate 1 is located in an orthographic projection of the second support portion 24 on the substrate 1, and the upper electrodes 33 are connected by the first support portions 23 of the isolation structure 2 to enable the first support portions 23 and the upper electrodes 33 to constitute common electrodes for driving.

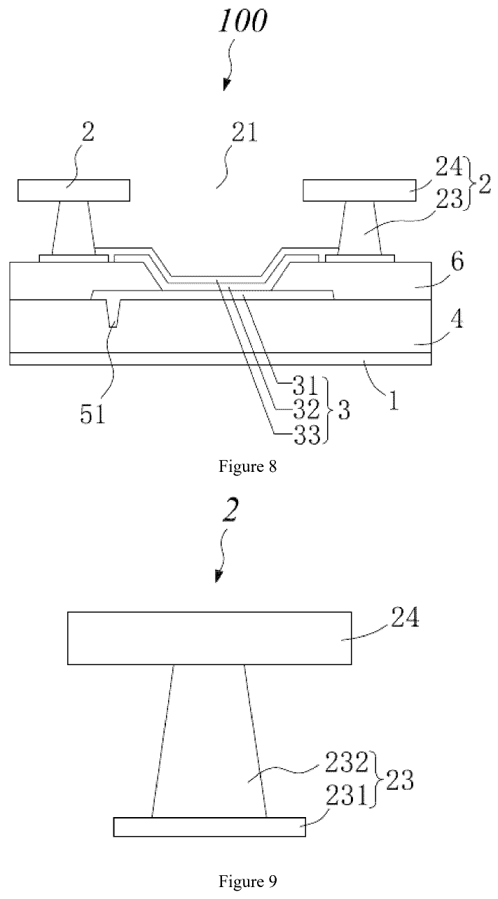

Referring to FIGS. 8 and 9, in one of the embodiments, the first support portion 23 includes a first sub-support portion 231 and a second sub-support portion 232, the first sub-support portion 231 is located between the second sub-support portion 232 and the substrate 1, and an orthographic projection of the second sub-support portion 232 on the substrate 1 is located in an orthographic projection of the first sub-support portion 231 on the substrate 1. In this way, at least a part of the isolation structure 2 away from the substrate 1 is in a shape that is wide at the top and narrow at the bottom, and the isolation structure 2 may block light-emitting layers 32 of adjacent light-emitting devices 3, to reduce current crosstalk of the adjacent light-emitting devices 3.

Referring to FIGS. 3-7, another embodiment of the present application discloses a display panel 100 which includes a substrate 1, a drive circuit layer 4, a pixel definition layer 6, an isolation structure 2, and a plurality of light-emitting devices 3.

The drive circuit layer 4 is disposed on a side of the substrate 1. The drive circuit layer 4 is provided with a plurality of pixel drive units and a plurality of vias 51. The plurality of pixel drive units include a plurality of first pixel drive units, a plurality of second pixel drive units, and a plurality of third pixel drive units. The plurality of vias 51 include a plurality of first vias 511, a plurality of second vias 512, and a plurality of third vias 513.

The pixel definition layer 6 is disposed on a side of the drive circuit layer 4 away from the substrate 1. The pixel definition layer 6 defines a plurality of pixel openings 61, and the plurality of pixel openings 61 include a plurality of first pixel openings 611, a plurality of second pixel openings 612, and a plurality of third pixel openings 613.

The isolation structure 2 is disposed on a side of the pixel definition layer 6 away from the substrate 1. The isolation structure 2 encloses a plurality of isolation openings 21, and the isolation openings 21 are in communication with corresponding pixel openings 61.

The plurality of light-emitting devices 3 include a plurality of first light-emitting devices, a plurality of second light-emitting devices, and a plurality of third light-emitting devices. The first light-emitting device is partially disposed in a corresponding one of the plurality of first pixel openings 611 and is electrically connected to a corresponding one of the plurality of first pixel drive units through a corresponding one of the plurality of first vias 511, the second light-emitting device is partially disposed in a corresponding one of the plurality of second pixel openings 612 and is electrically connected to a corresponding one of the plurality of second pixel drive units through a corresponding one of the plurality of second vias 512, and the third light-emitting device is partially disposed in a corresponding one of the plurality of third pixel openings 613 and is electrically connected to a corresponding one of the plurality of third pixel drive units through a corresponding one of the plurality of third vias 513.

An orthographic projection of the first via 511 on the substrate 1 is at a first shortest distance a from an orthographic projection of the corresponding first pixel opening 611 on the substrate 1, an orthographic projection of the second via 512 on the substrate 1 is at a second shortest distance b from an orthographic projection of the corresponding second pixel opening 612 on the substrate 1, and an orthographic projection of the third via 513 on the substrate 1 is at a third shortest distance c from an orthographic projection of the corresponding third pixel opening 613 on the substrate 1, At least two of the first shortest distance a, the second shortest distance b and the third shortest distance c are not equal.

In the display panel 100 provided in this embodiment, the orthographic projection of each first via 511 on the substrate 1 is at the first shortest distance a from the orthographic projection of the corresponding first pixel opening 611 on the substrate 1, the orthographic projection of each second via 512 on the substrate 1 is at the second shortest distance b from the orthographic projection of the corresponding second pixel opening 612 on the substrate 1, and the orthographic projection of each third via 513 on the substrate 1 is at the third shortest distance c from the orthographic projection of the corresponding third pixel opening 613 on the substrate 1, at least two of the first shortest distance a, the second shortest distance b and the third shortest distance c being not equal, which is conducive to compressing the space outside the pixel openings, thereby increasing the pixel aperture ratio, enhancing the brightness of the display panel, and improving the display performance of the display panel.

Still referring to FIG. 4, in one of the embodiments, the first shortest distance a is not greater than the second shortest distance b, which is conducive to compressing the space outside the first pixel openings 611, thereby increasing the pixel aperture ratio.

Referring to FIG. 5, in one of the embodiments, an edge of the first pixel opening 611 includes a first straight portion C1 extending in a first direction (e.g., a Y direction in the figure) and a concave portion 62 that is concave toward the first straight portion C1. The concave portion 62 includes a second straight portion C2 close to the first straight portion C1 in a second direction (e.g., an X direction in the figure), and the orthographic projection of the first via 511 on the substrate 1 is located on a side of an orthographic projection of the corresponding second straight portion C2 on the substrate 1 away from an orthographic projection of the corresponding first straight portion C1 on the substrate 1, the first direction intersecting with the second direction. A shortest distance between the orthographic projection of the first via 511 on the substrate 1 and the orthographic projection of the corresponding second straight portion C2 on the substrate 1 is the first shortest distance a. The concave portion 63 is configured to provide clearance for the corresponding first via 511, which is conducive to compressing the space outside the first pixel openings 611, thereby increasing the pixel aperture ratio.

The second direction may be at 70 degrees, 80 degrees, 85 degrees, etc. relative to the first direction. In some implementations, the second direction is at 90 degrees relative to the first direction, that is, the second direction is perpendicular to the first direction.

In some implementations, an edge of the second pixel opening 612 includes a plurality of third straight portions C3 extending in the first direction and a plurality of fourth straight portions C4 extending in the second direction, and a shortest distance between the orthographic projection of the second via on the substrate 1 and an orthographic projection of the corresponding fourth straight portion C4 on the substrate 1 is the second shortest distance b.

In some implementations, a length of the second straight portion C2 is less than a length of the first straight portion C1.

In some implementations, the first straight portion C1 is parallel to the second straight portion C2.

In some implementations, the first shortest distance a is not greater than the third shortest distance c.

In one of the embodiments, an edge of the third pixel opening 613 includes a plurality of fifth straight portions C5 extending in the first direction and a plurality of sixth straight portions C6 extending in the second direction, and a shortest distance between the orthographic projection of the third via 513 on the substrate 1 and an orthographic projection of the corresponding sixth straight portion C6 on the substrate 1 is the third shortest distance c.

Referring to FIG. 6, in one of the embodiments, the orthographic projection of each second via 512 on the substrate 1 is at a fourth shortest distance d from an orthographic projection of the adjacent third pixel opening 613 on the substrate 1, and the fourth shortest distance d is not equal to the second shortest distance b, which is conducive to compressing the space outside the pixel openings, thereby increasing the pixel aperture ratio.

In some implementations, the fourth shortest distance d is greater than the second shortest distance b.

In some implementations, the shortest distance between the orthographic projection of the second via 512 on the substrate 1 and an orthographic projection of the corresponding sixth straight portion C6 on the substrate 1 is the fourth shortest distance d.

In some implementations, the orthographic projection of the third via 513 on the substrate 1 is at a fifth shortest distance e from an orthographic projection of the adjacent second pixel opening 612 on the substrate 1, and the fifth shortest distance e is not equal to the third shortest distance c. The distances between each via and other pixel openings are set to be less than the distance between this via and the corresponding pixel opening, thereby increasing the pixel aperture ratio.

In some implementations, the fifth shortest distance e is greater than the third shortest distance c.

In some implementations, the shortest distance between the orthographic projection of the third via 513 on the substrate 1 and an orthographic projection of the corresponding fourth straight portion C4 on the substrate 1 is the fifth shortest distance e.

In some implementations, the orthographic projections of the second via 512 and third via 513 on the substrate 1 are located between the orthographic projection of the corresponding second pixel opening 612 on the substrate 1 and the orthographic projection of the corresponding third pixel opening 613 on the substrate 1, thereby increasing the pixel aperture ratio.

Still referring to FIG. 6, in one of the embodiments, the concave portion 62 has a first dimension in the first direction, and the concave portion 62 has a second dimension in the second direction, the first dimension being greater than the second dimension, which is conducive to further compressing of the space outside the first pixel openings 611, thereby increasing the pixel aperture ratio.

The influence of the dimension of the concave portion 62 in the second direction on the pixel aperture ratio is greater than that of the dimension of the concave portion 62 in the first direction on the pixel aperture ratio. Therefore, in this embodiment, the maximum dimension of the concave portion 62 in the second direction is set to be relatively small to ensure that the dimension of the pixel opening 61 in the second direction is large enough, while the maximum dimension of the concave portion 62 in the first direction is set to be relatively large to meet the requirement of an extreme distance between the pixel opening 61 and the via 51, thereby avoiding interference between the via 51 and the pixel opening 61.

In some implementations, the first dimension and the second dimension satisfy M>1.5 n, where m is the first dimension, and n is the second dimension. For example, m=1.6 n, m=1.7 n, m=1.8 n, m=2 n, etc. The pixel aperture ratio can be further increased based on this dimension relationship. In some implementations, m>2 n, for example, M=2.1 n, m=2.5 n, m=3 n, m=4 n, etc.

Another embodiment of the present application discloses a display apparatus including a display panel 100 as described in the above embodiments. The display apparatus may be a smart device (e.g., a mobile phone, a VR device, a computer, a television, or vehicle display).

In the display apparatus in this embodiment, in the display panel 100, an orthographic projection of each first via 511 on a substrate 1 is at a first shortest distance a from an orthographic projection of the corresponding first pixel opening 611 on the substrate 1, and an orthographic projection of each second via 512 on the substrate 1 is at a second shortest distance b from an orthographic projection of the corresponding second pixel opening 612 on the substrate 1, the first shortest distance a being not equal to the second shortest distance b, which is conducive to compressing the space outside the pixel openings, thereby increasing the pixel aperture ratio, enhancing the brightness of the display panel, improving the display performance of the display panel, and improving the display performance of the display apparatus.

The embodiments of the present application are intended to cover all such substitutions, modifications, and variations that fall within the broad scope of the appended claims. Therefore, any omissions, modifications, equivalent substitutions, improvements etc., made within the spirit and principle of the embodiments of the present application are intended to be included within the scope of protection of the present application.

1. A display panel, comprising:
a substrate;
a drive circuit layer disposed on a side of the substrate and provided with a plurality of pixel drive units and a plurality of vias, the plurality of pixel drive units comprising a plurality of first pixel drive units and a plurality of second pixel drive units, and the plurality of vias comprising a plurality of first vias and a plurality of second vias;
a pixel definition layer disposed on a side of the drive circuit layer away from the substrate and defining a plurality of pixel openings, the plurality of pixel openings comprising a plurality of first pixel openings and a plurality of second pixel openings; and
a plurality of light-emitting devices comprising a plurality of first light-emitting devices and a plurality of second light-emitting devices, the first light-emitting device being partially disposed in a corresponding one of the plurality of first pixel openings and electrically connected to a corresponding one of the plurality of first pixel drive units through a corresponding one of the plurality of first vias, and the second light-emitting device being disposed in a corresponding one of the plurality of second pixel openings and electrically connected to a corresponding one of the plurality of second pixel drive units through a corresponding one of the plurality of second vias;
wherein an orthographic projection of the first via on the substrate is at a first shortest distance from an orthographic projection of the corresponding first pixel opening on the substrate, and an orthographic projection of the second via on the substrate is at a second shortest distance from an orthographic projection of the corresponding second pixel opening on the substrate, the first shortest distance being not equal to the second shortest distance.

2. The display panel according to claim 1, wherein
an edge of the first pixel opening comprises a first straight portion extending in a first direction and a concave portion that is concave toward the first straight portion, the concave portion comprising a second straight portion close to the first straight portion in a second direction, the orthographic projection of the first via on the substrate being located on a side of an orthographic projection of the corresponding second straight portion on the substrate away from an orthographic projection of the corresponding first straight portion on the substrate, the first direction intersecting with the second direction, and a shortest distance between the orthographic projection of the first via on the substrate and the orthographic projection of the corresponding second straight portion on the substrate being the first shortest distance; and
an edge of the second pixel opening comprises a plurality of third straight portions extending in the first direction and a plurality of fourth straight portions extending in the second direction, a shortest distance between the orthographic projection of the second via on the substrate and an orthographic projection of the corresponding fourth straight portion on the substrate being the second shortest distance.

3. The display panel according to claim 2, wherein the first shortest distance is not greater than the second shortest distance, and a length of the second straight portion is less than a length of the first straight portion;
the first direction is perpendicular to the second direction; and
the first straight portion is parallel to the second straight portion.

4. The display panel according to claim 2, wherein an emitting color of the first light-emitting device is different from an emitting color of the second light-emitting device;
the plurality of pixel drive units further comprise a plurality of third pixel drive units, the plurality of vias further comprise a plurality of third vias, the plurality of pixel openings further comprise a plurality of third pixel openings, and the plurality of light-emitting devices further comprise a plurality of third light-emitting devices, the third light-emitting device partially disposed in a corresponding one of the plurality of third pixel openings and electrically connected to a corresponding one of the plurality of third pixel drive units through a corresponding one of the plurality of third vias, wherein an orthographic projection of the third via on the substrate is at a third shortest distance from an orthographic projection of a corresponding one of the plurality of third pixel openings on the substrate;
the first shortest distance is not greater than the third shortest distance;
an edge of the third pixel opening comprises a plurality of fifth straight portions extending in the first direction and a plurality of sixth straight portions extending in the second direction, and a shortest distance between the orthographic projection of the third via on the substrate and an orthographic projection of the corresponding sixth straight portion on the substrate is the third shortest distance; and
the emitting color of the first light-emitting device, the emitting color of the second light-emitting device, and an emitting color of the third light-emitting device are different from each other.

5. The display panel according to claim 4, wherein the orthographic projection of the second via on the substrate is at a fourth shortest distance from an orthographic projection of the third pixel opening adjacent to the second via on the substrate, the fourth shortest distance being not equal to the second shortest distance;
the shortest distance between the orthographic projection of the second via on the substrate and the orthographic projection of the corresponding sixth straight portion on the substrate is the fourth shortest distance;
the orthographic projection of the third via on the substrate is at a fifth shortest distance from an orthographic projection of the second pixel opening adjacent to the third via on the substrate, the fifth shortest distance being not equal to the third shortest distance; and
the shortest distance between the orthographic projection of the third via on the substrate and the orthographic projection of the corresponding fourth straight portion on the substrate is the fifth shortest distance.

6. The display panel according to claim 5, wherein the orthographic projections of the second via and the third via on the substrate are located between the orthographic projection of the corresponding second pixel opening on the substrate and the orthographic projection of the corresponding third pixel opening on the substrate, the fourth shortest distance is greater than the second shortest distance, and the fifth shortest distance is greater than the third shortest distance.

7. The display panel according to claim 2, wherein the concave portion has a first dimension in the first direction, and the concave portion has a second dimension in the second direction, wherein the first dimension is greater than the second dimension; and
the first dimension and the second dimension satisfy m>1.5 n, where m is the first dimension, and n is the second dimension.

8. The display panel according to claim 4, wherein the concave portion further comprises:
a seventh straight portion and a first curved portion, the first curved portion being connected to a first end of the second straight portion and a first end of the seventh straight portion, and an included angle between the second straight portion and the seventh straight portion being not less than 90 degrees; and
an eighth straight portion and a second curved portion, the second curved portion being connected to a second end of the second straight portion and a first end of the eighth straight portion, and an included angle between the second straight portion and the eighth straight portion being not less than 90 degrees;
wherein the seventh straight portion and the eighth straight portion are located on a side of the second straight portion away from the first straight portion;
the edge of the first pixel opening further comprises:
a ninth straight portion and a tenth straight portion which are located on the side of the second straight portion away from the first straight portion, and a portion of the orthographic projection of the first via on the substrate being located between an orthographic projection of the ninth straight portion on the substrate and an orthographic projection of the tenth straight portion on the substrate; and
a third curved portion and a fourth curved portion, the third curved portion being connected to a second end of the seventh straight portion and a first end of the ninth straight portion, an included angle between the seventh straight portion and the ninth straight portion being not less than 90 degrees, the fourth curved portion being connected to a second end of the eighth straight portion and a first end of the tenth straight portion, and an included angle between the eighth straight portion and the tenth straight portion being not less than 90 degrees;
wherein the ninth straight portion is parallel to the first straight portion, and the tenth straight portion is parallel to the first straight portion;
the edge of the first pixel opening further comprises:
an eleventh straight portion, a fifth curved portion, and a sixth curved portion, the fifth curved portion being connected to a first end of the first straight portion and a first end of the eleventh straight portion, the sixth curved portion being connected to a second end of the eleventh straight portion and a second end of the ninth straight portion, and the eleventh straight portion extending in the second direction; and
a twelfth straight portion, a seventh curved portion, and an eighth curved portion, the seventh curved portion being connected to a second end of the first straight portion and a first end of the twelfth straight portion, the eighth curved portion being connected to a second end of the twelfth straight portion and a second end of the tenth straight portion, and the twelfth straight portion extending in the second direction;
wherein a length of the first straight portion is greater than a length of the eleventh straight portion, and the length of the first straight portion is greater than a length of the twelfth straight portion; and
an included angle between the eleventh straight portion and the first straight portion is not less than 90 degrees, an included angle between the eleventh straight portion and the ninth straight portion is not less than 90 degrees, an included angle between the twelfth straight portion and the first straight portion is not less than 90 degrees, and an included angle between the twelfth straight portion and the tenth straight portion is not less than 90 degrees;
the edge of the second pixel opening further comprises:
a plurality of ninth curved portions, the ninth curved portion being connected between the corresponding adjacent third straight portion and fourth straight portion, an included angle between the third straight portion and the fourth straight portion being not less than 90 degrees; and
the edge of the third pixel opening further comprises:
a plurality of tenth curved portions, the tenth curved portion being connected between the corresponding adjacent fifth straight portion and sixth straight portion, an included angle between the fifth straight portion and the sixth straight portion being not less than 90 degrees.

9. The display panel according to claim 4, wherein the first light-emitting device comprises a first lower electrode, the second light-emitting device comprises a second lower electrode, and the third light-emitting device comprises a third lower electrode, wherein a part of a structure of the first lower electrode extends to the corresponding first via and is electrically connected to the corresponding first pixel drive unit, a part of a structure of the second lower electrode extends to the corresponding second via and is electrically connected to the corresponding second pixel drive unit, and a part of a structure of the third lower electrode extends to the corresponding third via and is electrically connected to the corresponding third pixel drive unit; and
a portion of the first lower electrode is disposed between the drive circuit layer and the pixel definition layer, and the other portion is exposed from the corresponding first pixel opening; a portion of the second lower electrode is disposed between the drive circuit layer and the pixel definition layer, and the other portion is exposed from the corresponding second pixel opening; and a portion of the third lower electrode is disposed between the drive circuit layer and the pixel definition layer, and the other portion is exposed from the corresponding third pixel opening.

10. The display panel according to claim 4, wherein the emitting color of the first light-emitting device is blue, the emitting color of the second light-emitting device is either red or green, and the emitting color of the third light-emitting device is the other one of red and green; and
an area of the first pixel opening is greater than an area of the second pixel opening, and the area of the first pixel opening is greater than an area of the third pixel opening.

11. The display panel according to claim 4, comprising a plurality of pixels which are arranged in an array and comprise the first light-emitting devices, the second light-emitting devices and the third light-emitting devices, wherein
in the same pixel, the orthographic projection of the second via corresponding to the second light-emitting device on the substrate and the orthographic projection of the third via corresponding to the third light-emitting device on the substrate are located between the orthographic projection of the second pixel opening corresponding to the second light-emitting device on the substrate and the orthographic projection of the third pixel opening corresponding to the third light-emitting device on the substrate; and
in the same pixel, the first light-emitting device and the second light-emitting device are arranged in the second direction, the first light-emitting device and the third light-emitting device are arranged in the second direction, the second light-emitting device and the third light-emitting device are arranged in the first direction, and the second light-emitting device and the third light-emitting device are on the same side of the first light-emitting device.

12. The display panel according to claim 4, comprising a plurality of first pixel columns and a plurality of second pixel columns which are arranged alternately in the second direction, wherein the first pixel column comprises a plurality of first light-emitting devices arranged in the first direction, and the second pixel column comprises a plurality of second light-emitting devices and a plurality of third light-emitting devices which are arranged alternately in the first direction.

13. The display panel according to claim 1, further comprising:
an isolation structure disposed on a side of the pixel definition layer away from the substrate and enclosing a plurality of isolation openings in communication with corresponding pixel openings;
the isolation structure comprising:
a first support portion and a second support portion, wherein the second support portion is located on a side of the first support portion away from the substrate, and an orthographic projection of an end of the first support portion close to the second support portion on the substrate is located in an orthographic projection of the second support portion on the substrate; and
the first support portion comprises a first sub-support portion and a second sub-support portion, the first sub-support portion being located between the second sub-support portion and the substrate, and an orthographic projection of the second sub-support portion on the substrate being located in an orthographic projection of the first sub-support portion on the substrate.

14. A display panel, comprising:
a substrate;
a drive circuit layer disposed on a side of the substrate and provided with a plurality of pixel drive units and a plurality of vias, the plurality of pixel drive units comprising a plurality of first pixel drive units, a plurality of second pixel drive units, and a plurality of third pixel drive units, and the plurality of vias comprising a plurality of first vias, a plurality of second vias, and a plurality of third vias;
a pixel definition layer disposed on the side of the drive circuit layer away from the substrate and defining a plurality of pixel openings, the plurality of pixel openings comprising a plurality of first pixel openings, a plurality of second pixel openings, and a plurality of third pixel openings;
an isolation structure disposed on a side of the pixel definition layer away from the substrate and enclosing a plurality of isolation openings in communication with corresponding pixel openings; and
a plurality of light-emitting devices comprising a plurality of first light-emitting devices, a plurality of second light-emitting devices, and a plurality of third light-emitting devices, the first light-emitting device being partially disposed in a corresponding one of the plurality of first pixel openings and electrically connected to a corresponding one of the plurality of first pixel drive units through a corresponding one of the plurality of first vias, the second light-emitting device being disposed in a corresponding one of the plurality of second pixel openings and electrically connected to a corresponding one of the plurality of second pixel drive units through a corresponding one of the plurality of second vias, and the third light-emitting device being disposed in a corresponding one of the plurality of third pixel openings and electrically connected to a corresponding one of the plurality of third pixel drive units through a corresponding one of the plurality of third vias;
wherein an orthographic projection of the first via on the substrate is at a first shortest distance from an orthographic projection of the corresponding first pixel opening on the substrate, an orthographic projection of the second via on the substrate is at a second shortest distance from an orthographic projection of the corresponding second pixel opening on the substrate, and an orthographic projection of the third via on the substrate is at a third shortest distance from an orthographic projection of the corresponding third pixel opening on the substrate, at least two of the first shortest distance, the second shortest distance and the third shortest distance being not equal.

15. The display panel according to claim 14, wherein
an edge of the first pixel opening comprises a first straight portion extending in a first direction and a concave portion that is concave toward the first straight portion, the concave portion comprising a second straight portion close to the first straight portion in a second direction, the orthographic projection of the first via on the substrate being located on a side of an orthographic projection of the corresponding second straight portion on the substrate away from an orthographic projection of the corresponding first straight portion on the substrate, the first direction intersecting with the second direction, and a shortest distance between the orthographic projection of the first via on the substrate and the orthographic projection of the corresponding second straight portion on the substrate being the first shortest distance; and
an edge of the second pixel opening comprises a plurality of third straight portions extending in the first direction and a plurality of fourth straight portions extending in the second direction, a shortest distance between the orthographic projection of the second via on the substrate and an orthographic projection of the corresponding fourth straight portion on the substrate being the second shortest distance.

16. The display panel according to claim 15, wherein the first shortest distance is not greater than the second shortest distance, and a length of the second straight portion is less than a length of the first straight portion;
the first direction is perpendicular to the second direction;
the first straight portion is parallel to the second straight portion; and
the emitting color of the first light-emitting device, the emitting color of the second light-emitting device, and an emitting color of the third light-emitting device are different from each other.

17. The display panel according to claim 15, wherein the first shortest distance is not greater than the third shortest distance; and
an edge of the third pixel opening comprises a plurality of fifth straight portions extending in the first direction and a plurality of sixth straight portions extending in the second direction, and a shortest distance between the orthographic projection of the third via on the substrate and an orthographic projection of the corresponding sixth straight portion on the substrate is the third shortest distance.

18. The display panel according to claim 17, wherein the orthographic projection of the second via on the substrate is at a fourth shortest distance from an orthographic projection of the third pixel opening adjacent to the second via on the substrate, the fourth shortest distance being not equal to the second shortest distance;
the shortest distance between the orthographic projection of the second via on the substrate and the orthographic projection of the corresponding sixth straight portion on the substrate is the fourth shortest distance;
the orthographic projection of the third via on the substrate is at a fifth shortest distance from an orthographic projection of the second pixel opening adjacent to the third via on the substrate, the fifth shortest distance being not equal to the third shortest distance; and
the shortest distance between the orthographic projection of the third via on the substrate and the orthographic projection of the corresponding fourth straight portion on the substrate is the fifth shortest distance.

19. The display panel according to claim 18, wherein the orthographic projections of the second via and the third via on the substrate are located between the orthographic projection of the corresponding second pixel opening on the substrate and the orthographic projection of the corresponding third pixel opening on the substrate, the fourth shortest distance is greater than the second shortest distance, and the fifth shortest distance is greater than the third shortest distance;
the concave portion has a first dimension in the first direction, and the concave portion has a second dimension in the second direction, wherein the first dimension is greater than the second dimension; and
the first dimension and the second dimension satisfy m>1.5 n, where m is the first dimension, and n is the second dimension.

20. A display apparatus, comprising:
a display panel, comprising:
a substrate;
a drive circuit layer disposed on a side of the substrate and provided with a plurality of pixel drive units and a plurality of vias, the plurality of pixel drive units comprising a plurality of first pixel drive units and a plurality of second pixel drive units, and the plurality of vias comprising a plurality of first vias and a plurality of second vias;
a pixel definition layer disposed on a side of the drive circuit layer away from the substrate and defining a plurality of pixel openings, the plurality of pixel openings comprising a plurality of first pixel openings and a plurality of second pixel openings; and
a plurality of light-emitting devices comprising a plurality of first light-emitting devices and a plurality of second light-emitting devices, the first light-emitting device being partially disposed in a corresponding one of the plurality of first pixel openings and electrically connected to a corresponding one of the plurality of first pixel drive units through a corresponding one of the plurality of first vias, and the second light-emitting device being disposed in a corresponding one of the plurality of second pixel openings and electrically connected to a corresponding one of the plurality of second pixel drive units through a corresponding one of the plurality of second vias;
wherein an orthographic projection of the first via on the substrate is at a first shortest distance from an orthographic projection of the corresponding first pixel opening on the substrate, and an orthographic projection of the second via on the substrate is at a second shortest distance from an orthographic projection of the corresponding second pixel opening on the substrate, the first shortest distance being not equal to the second shortest distance.
